(19) United States
(12) Patent Application Publication
(10) Pub. No.: US 2025/0084274 A1
(43) Pub. Date: Mar. 13, 2025

(54) CURABLE COMPOSITION, CURED PRODUCT FORMED FROM THE SAME AND USE OF THE SAME

(71) Applicant: DAXIN MATERIALS CORP., Taichung City (TW)

(72) Inventors: Yun-Ching WU, Taichung City (TW); Yu-Lin HUANG, Taichung City (TW); Ming-Tsung TSAI, Taichung City (TW); Pei-Nung CHEN, Taichung City (TW); Shu-Wei CHANG, Taichung City (TW); Ming-Tsung HSU, Taichung City (TW)

(21) Appl. No.: 18/883,969

(22) Filed: Sep. 12, 2024

(30) Foreign Application Priority Data
Sep. 13, 2023 (TW) 112134905

(51) Int. Cl. C09D 163/00; C08G 59/32; C08G 59/38; C08G 59/50; C08K 7/18; C09D 7/40; C09D 7/61; H01L 21/56; H01L 23/00; H01L 23/29

(52) U.S. Cl. CPC C09D 163/00; C08G 59/3218; C08G 59/38; C08G 59/5033; C08K 7/18; C09D 7/61; C09D 7/70; H01L 23/295; H01L 21/563; H01L 24/29; H01L 24/32; H01L 2224/2929; H01L 2224/29386; H01L 2224/29499; H01L 2224/32225; H01L 2924/05432; H01L 2924/05442

(57) ABSTRACT

A curable composition includes an epoxy monomer component and an aniline-based hardener. The epoxy monomer component is a first component formed from a first epoxy monomer represented by Formula (I), or a second component including the first epoxy monomer represented by Formula (I) and a second epoxy monomer different from the first epoxy monomer represented by Formula (I), wherein each of the substituents in Formula (I) is given the definitions as set forth in the Specification and Claims. Based on 100 wt % of the epoxy monomer component, an amount of the first epoxy monomer represented by Formula (I) is not smaller than 25 wt % and less than 100 wt % and an amount of the second epoxy monomer is greater than 0% and not greater than 75 wt %. A cured product formed from the curable composition, and a method for encapsulating a semiconductor device using the curable composition are also provided.

### CROSS-REFERENCE TO RELATED APPLICATION

This application claims priority to Taiwanese Invention Patent Application No. 112134905, filed on Sep. 13, 2023, and incorporated by reference herein in its entirety.

### FIELD

The present disclosure relates to a curable composition, a cured product formed from the curable composition, and use of the curable composition.

### BACKGROUND

CN 110036070 A discloses a resin composition for sealing which includes, based on 100 wt % of the resin composition, 10 wt % to 50 wt % of an epoxy resin, 1 wt % to 50 wt % of a curing agent having amine group, not greater than 3 wt % of a resin having phenoxy group, and 40 wt % to 85 wt % of an inorganic filler material. Examples of the epoxy resin include, cresol novolac epoxy resin, glycidyl ester epoxy resin, glycidyl amine epoxy resin, etc. An example of the glycidyl amine epoxy resin includes para-(2,3-epoxypropoxy)-N,N-bis(2,3-epoxypropyl)aniline (triglycidyl p-aminophenol), etc. The resin composition for sealing has a viscosity ranging from 0.1 Pa·s to 100 Pa·s at 25° C. and appropriate fluidity, so the resin composition can be filled and disposed in the gap between a carrier plate (e.g., a metallic conductive substrate) and an electronic component (e.g., a semiconductor chip) of an electronic device based on the principle of capillary action, thereby encapsulating the electronic device.

Although the resin composition for filing has appropriate fluidity and can be used as an underfill material in flip-chips, a cured product formed from such resin composition easily absorbs moisture, resulting in the water vapor in the cured product easily generates bubbles, such that during reliability testing at high temperature, the existence of the bubbles might cause the encapsulated electronic device to crack easily. As such, the encapsulated electronic device has a problem of poor yield.

In view of the aforesaid, those skilled in the art strive to develop a material that has appropriate flowability and that is capable of forming a cured product with low hygroscopicity.

### SUMMARY

Therefore, an object of the present disclosure is to provide a curable composition, a cured product, and a method for encapsulating a semiconductor device that can alleviate at least one of the drawbacks of the prior art.

According to an aspect of the present disclosure, the curable composition includes an epoxy monomer component and at least one of an aniline-based hardener. The epoxy monomer component is selected from one of a first component and a second component. The first component is formed from at least one of a first epoxy monomer represented by Formula (I). The second component includes the at least one of the first epoxy monomer represented by Formula (I) and at least one of a second epoxy monomer that is different from the first epoxy monomer represented by Formula (I),

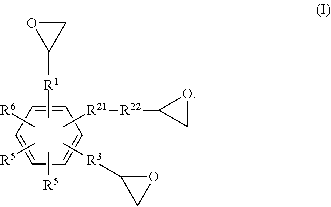

In formula (I), each of R¹, R²² and R³ is independently a C₁-C₃ alkylene group, R²¹ is one of a single bond and oxygen, and each of R⁴, R⁵ and R⁶ is independently one of hydrogen and a C₁-C₃ alkyl group. Based on 100 wt % of the epoxy monomer component, the first epoxy monomer represented by Formula (I) is present in an amount of not smaller than 25 wt % and less than 100 wt % and the second epoxy monomer is present in an amount of greater than 0% and not greater than 75 wt %.

According to another aspect of the present disclosure, the cured product is formed by subjecting the aforesaid curable composition to a curing reaction.

According to yet another aspect of the present disclosure, a method for encapsulating a semiconductor device includes introducing the aforesaid curable composition into a gap between a carrier and a semiconductor element of the semiconductor device, followed by conducting a curing reaction.

### DETAILED DESCRIPTION

Before the present disclosure is described in greater detail, it should be noted that if any prior art publication is referred to herein, such reference does not constitute an admission that the publication forms a part of the common general knowledge in the art, in Taiwan or any other country.

For the purpose of this specification, it will be clearly understood that the word “comprising” means “including but not limited to”, and that the word “comprises” has a corresponding meaning.

Unless otherwise defined, all technical and scientific terms used herein have the meaning commonly understood by a person skilled in the art to which the present disclosure belongs. One skilled in the art will recognize many methods and materials similar or equivalent to those described herein, which could be used in the practice of the present disclosure. Indeed, the present disclosure is in no way limited to the methods and materials described.

The present disclosure provides a curable composition which includes an epoxy monomer component and at least one of a hardener. The epoxy monomer component is selected from one of a first component and a second component. The first component is formed from at least one of a first epoxy monomer represented by Formula (I). The second component includes the at least one of the first epoxy monomer represented by Formula (I) and at least one of a second epoxy monomer that is different from the first epoxy monomer represented by Formula (I),

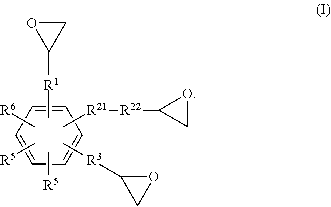

In Formula (I), each of R¹, R²² and R³ is independently a C₁-C₃ alkylene group, R²¹ is one of a single bond and oxygen, and each of R⁴, R⁵ and R⁶ is independently one of hydrogen and a C₁-C₃ alkyl group. Based on 100 wt % of the epoxy monomer component, the first epoxy monomer represented by Formula (I) is present in an amount of not smaller than 25 wt % and less than 100 wt % and the second epoxy monomer is present in an amount of greater than 0% and not greater than 75 wt %.

In certain embodiments, the epoxy monomer component is present in an amount ranging from 5 wt % to 65 wt % based on 100 wt % of the curable composition. In certain embodiments, the epoxy monomer component is present in an amount ranging from 20 wt % to 65 wt % based on 100 wt % of the curable composition.

In certain embodiments, the epoxy monomer component is the first component.

In certain embodiments, the first epoxy monomer represented by Formula (I) is selected from the group consisting of an epoxy monomer represented by Formula (I-1)

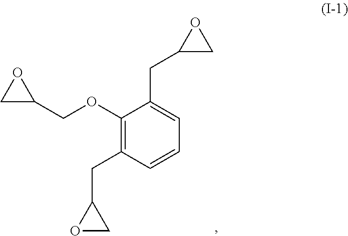 [SMILES: c1cc(CC2CO2)c(OCC2CO2)c(CC2CO2)c1]

an epoxy monomer represented by Formula (I-2)

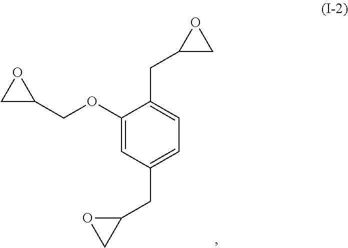 [SMILES: c1cc(CC2CO2)c(OCC2CO2)cc1CC1CO1]

an epoxy monomer represented by Formula (I-3)

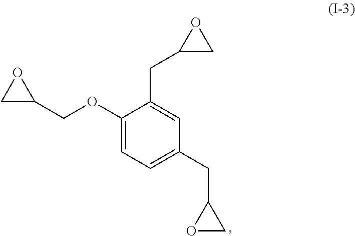 [SMILES: c1cc(OCC2CO2)c(CC2CO2)cc1CC1CO1]

an epoxy monomer represented by Formula (I-4)

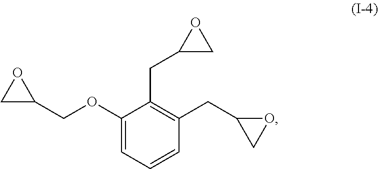 [SMILES: c1cc(CC2CO2)c(CC2CO2)c(OCC2CO2)c1]

and an epoxy monomer represented by Formula (I-5)

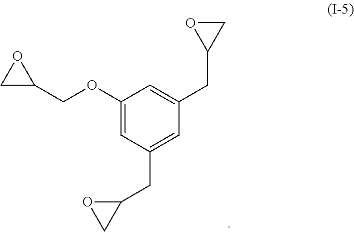 [SMILES: c1c(CC2CO2)cc(OCC2CO2)cc1CC1CO1]

In certain embodiments, the epoxy monomer component is the second component which includes at least one the first epoxy monomer represented by Formula (I) and at least one the second epoxy monomer that is different from the first epoxy monomer represented by Formula (I), and based on 100 wt % of the epoxy monomer component, the first epoxy monomer represented by Formula (I) is present in an amount of not smaller than 25 wt % and less than 100 wt % and the second epoxy monomer is present in an amount of greater than 0% and not greater than 75 wt %. In certain embodiments, the first epoxy monomer represented by Formula (I) is present in an amount of not smaller than 60 wt % and less than 100 wt % based on 100 wt % of the epoxy monomer component.

In consideration of providing a cured product formed from the curable composition with a relatively high glass transition temperature and a good adhesion strength, the second epoxy monomer is, e.g., an epoxy monomer having two epoxy groups and a plurality of aromatic rings, but is not limited thereto. Examples of the epoxy monomer having the two epoxy groups and the plurality of aromatic rings include,

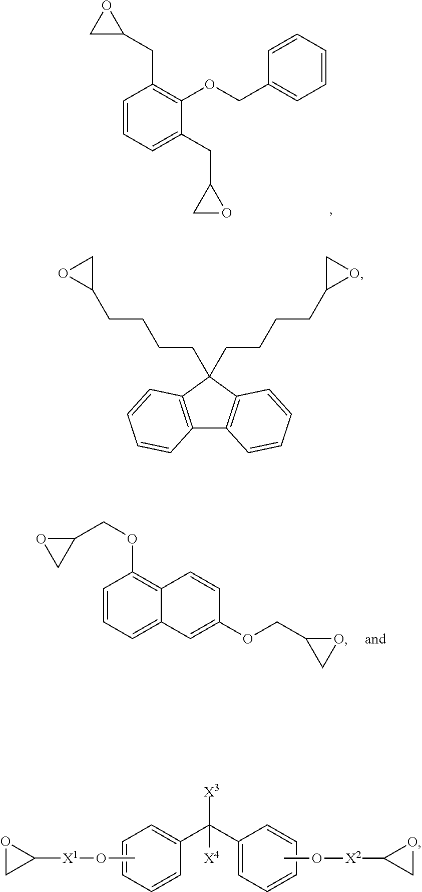

but are not limited thereto. In

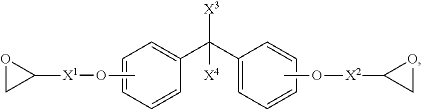

each of X¹ and X² is independently a C₁-C₃ alkylene group, and each of X³ and X⁴ is independently one of hydrogen and a methyl group. Examples of

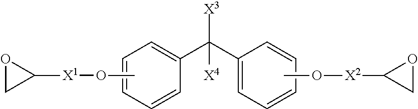

include, bisphenol F diglycidyl ether, bisphenol A diglycidyl ether, and

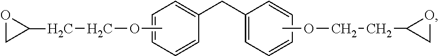

but are not limited thereto. In certain embodiments, the second epoxy monomer is the epoxy monomer having the two epoxy groups and the plurality of aromatic rings. In certain embodiments, the epoxy monomer having the two epoxy groups and the plurality of aromatic rings is selected from the group consisting of

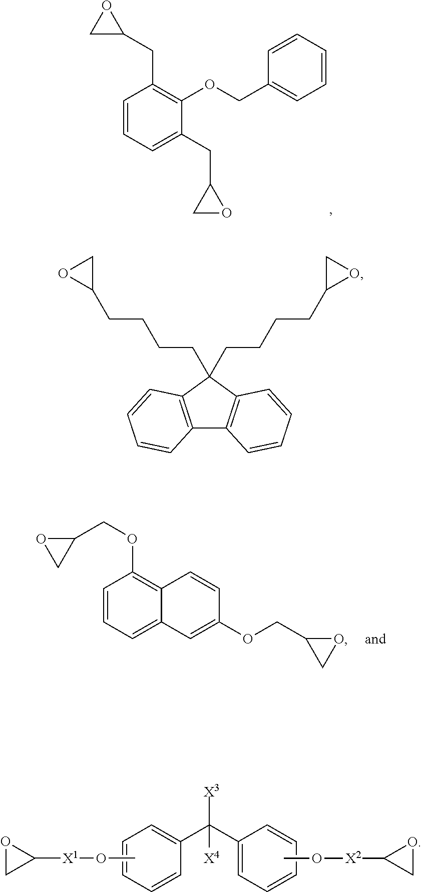

The hardener may be a single type of the hardener or a mixture of different types of the hardener. Examples of the hardener may include, an aniline-based hardener, an acid anhydride-based hardener, and a phenolic-based hardener, but are not limited thereto. Examples of the aniline-based hardener may include, 4,4′-methylenebis(2-ethylaniline), 4,4′-methylenebis(2-methyl-6-ethylaniline), and 4-methyl-2,6-bis(methylsulfanyl)benzene-1,3-diamine, but are not limited thereto. An example of the acid anhydride-based hardener may include, 4,5-dimethyl-7-(2-methyl-1-propen-1-yl)-3a,4,7,7a-tetrahydro-2-benzofuran-1,3-di one, but is not limited thereto. An example of the phenolic-based hardener may include, 4,4′-methylenebis(2-allylphenol), but is not limited thereto. In certain embodiments, the hardener is selected from the group consisting of the aniline-based hardener, the acid anhydride-based hardener, and the phenolic-based hardener. In certain embodiments, the hardener is present in an amount ranging from 11 wt % to 60 wt % based on 100 wt % of the curable composition. In certain embodiments, the hardener is present in an amount ranging from 11 wt % to 45 wt % based on 100 wt % of the curable composition.

In certain embodiments, the curable composition further includes at least one of a filler material. Examples of the filler material may include, alumina and spherical silica, but are not limited thereto. In certain embodiments, the filler material may be selected from the group consisting of the alumina and the spherical silica. In certain embodiments, the filler material is present in an amount of greater than 0 wt % and not greater than 70 wt % based on 100 wt % of the curable composition. In certain embodiments, the filler material is present in an amount ranging from 55 wt % to 70 wt % based on 100 wt % of the curable composition.

The present disclosure also provides a cured product, and which is formed by subjecting the aforesaid curable composition to a curing reaction. The curing reaction is conducted at a temperature ranging from 100° C. to 200° C. for a time period ranging from 0.5 hours to 3.0 hours.

According to the present disclosure, the cured product may serve as an underfill material that is disposed in a gap between a carrier and a semiconductor element of a semiconductor device to encapsulate the semiconductor device. Examples of the carrier may include, a printed circuit board, a ceramic substrate, and a conductive metal substrate, but are not limited thereto. Examples of the semiconductor element may include, a light-emitting diode chip and an integrated circuit chip, but are not limited thereto.

The present disclosure also provides a method for encapsulating the semiconductor device, which includes introducing the aforesaid curable composition into the gap between the carrier and the semiconductor element of the semiconductor device, followed by conducting the curing reaction.

The present disclosure will be described by way of the following examples. However, it should be understood that the following examples are intended solely for the purpose of illustration and should not be construed as limiting the present disclosure in practice.

### Preparation of Curable Composition

### Example 1 (EX1)

First, based on 100 wt % of a curable composition, a first epoxy monomer mixture [including an epoxy monomer represented by Formula (I-1)

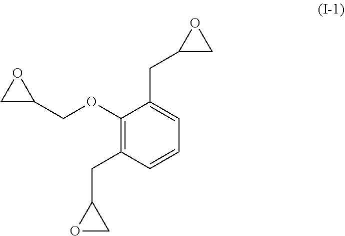 [SMILES: c1cc(CC2CO2)c(OCC2CO2)c(CC2CO2)c1]

in an amount of 14.42 wt % and an epoxy monomer represented by Formula (I-3)

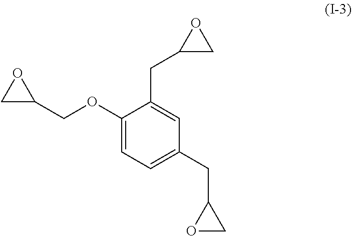 [SMILES: c1cc(OCC2CO2)c(CC2CO2)cc1CC1CO1]

in an amount of 8.08 wt %] in an amount of 22.5 wt % and bisphenol F diglycidyl ether (serving as a second epoxy monomer) in an amount of 8.1 wt % were mixed, so as to form an epoxy monomer component (i.e., a second component), wherein the first epoxy monomer is present in a total amount of 73.5 wt % in the epoxy monomer component. Next, based on 100 wt % of the curable composition, a hardener mixture in an amount of 14.4 wt % [including 4,4′-methylenebis(2-ethylaniline) in an amount of 9.36 wt % and 4,4′-methylenebis(2-methyl-6-ethylaniline) in an amount of 5.04 wt %] and spherical silica in an amount of 55 wt % were mixed with the epoxy monomer component, thereby obtaining a curable composition of EX1.

### Examples 2 and 3 (EX2 and EX3)

The procedures and conditions for preparing the curable compositions of EX2 and EX3 were substantially similar to those of EX1, except that the types and/or amounts of the components were altered (see Table 1 below). In EX2, on 100 wt % of the curable composition, the first epoxy monomer mixture includes the epoxy monomer represented by Formula (I-1)

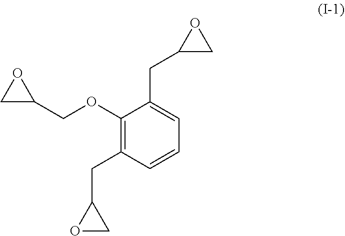 [SMILES: c1cc(CC2CO2)c(OCC2CO2)c(CC2CO2)c1]

in an amount of 8.84 wt % and the epoxy monomer represented by Formula (I-3)

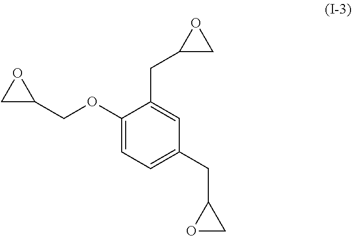 [SMILES: c1cc(OCC2CO2)c(CC2CO2)cc1CC1CO1]

in an amount of 4.96 wt %, while the hardener mixture includes 4,4′-methylenebis(2-ethylaniline) in an amount of 8.06 wt % and 4,4′-methylenebis(2-methyl-6-ethylaniline) in an amount of 4.34 wt %. In EX3, based on 100 wt % of the curable composition, the first epoxy monomer mixture includes the epoxy monomer represented by Formula (I-1)

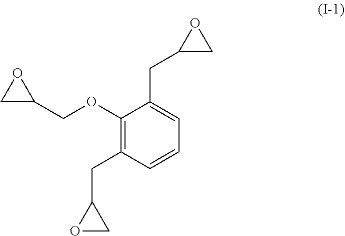 [SMILES: c1cc(CC2CO2)c(OCC2CO2)c(CC2CO2)c1]

in an amount of 25.19 wt % and the epoxy monomer represented by Formula (I-3)

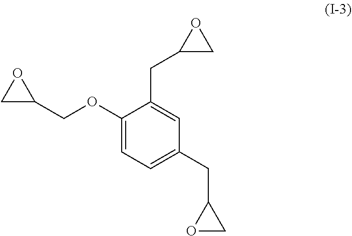 [SMILES: c1cc(OCC2CO2)c(CC2CO2)cc1CC1CO1]

in an amount of 14.11 wt %, while the hardener mixture includes 4,4′-methylenebis(2-ethylaniline) in an amount of 23.2 wt % and 4,4′-methylenebis(2-methyl-6-ethylaniline) in an amount of 12.5 wt %.

### Example 4 (EX4)

First, based on 100 wt % of a curable composition, an epoxy monomer represented by Formula (I-1)

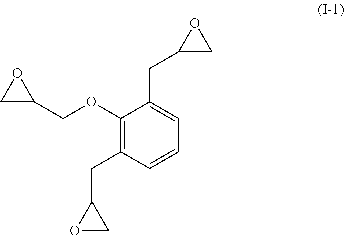 [SMILES: c1cc(CC2CO2)c(OCC2CO2)c(CC2CO2)c1]

in an amount of 36.47 wt % and an epoxy monomer represented by Formula (I-3)

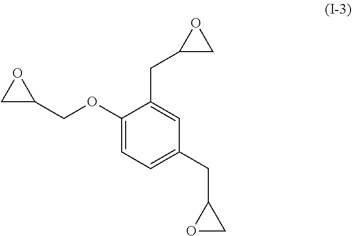 [SMILES: c1cc(OCC2CO2)c(CC2CO2)cc1CC1CO1]

in an amount of 20.43 wt % were mixed to form an epoxy monomer component (i.e., a first component). Next, based on 100 wt % of the curable composition, a hardener mixture in an amount of 43.1 wt % [including 4,4′-methylenebis(2-ethylaniline) in an amount of 28.015 wt % and 4,4′-methylenebis(2-methyl-6-ethylaniline) in an amount of 15.085 wt %] was mixed with the epoxy monomer component, thereby obtaining a curable composition of EX4.

### Example 5 (EX5)

First, based on 100 wt % of a curable composition, an epoxy monomer represented by Formula (I-1)

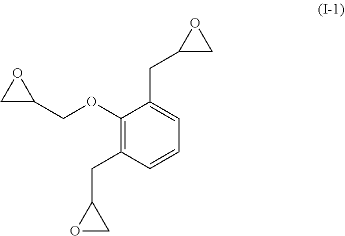 [SMILES: c1cc(CC2CO2)c(OCC2CO2)c(CC2CO2)c1]

in an amount of 18.91 wt % and an epoxy monomer represented by Formula (I-3)

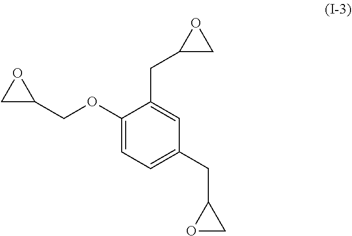 [SMILES: c1cc(OCC2CO2)c(CC2CO2)cc1CC1CO1]

in an amount of 10.59 wt % were mixed to form an epoxy monomer component (i.e., a first component). Next, based on 100 wt % of the curable composition, a hardener mixture in an amount of 15.5 wt % [including 4,4′-methylenebis(2-ethylaniline) in an amount of 10.075 wt % and 4,4′-methylenebis(2-methyl-6-ethylaniline) in an amount of 5.425 wt %] and spherical silica in an amount of 55 wt % were mixed with the epoxy monomer component, thereby obtaining a curable composition of EX5.

### Examples 6 to 8 (EX6 to EX8)

The procedures and conditions for preparing the curable compositions of EX6 to EX8 were substantially similar to those of EX1, except that the types and/or amounts of the components were altered (see Table 2 below). In EX6, based on 100 wt % of the curable composition, the first epoxy monomer mixture includes the epoxy monomer represented by Formula (I-1)

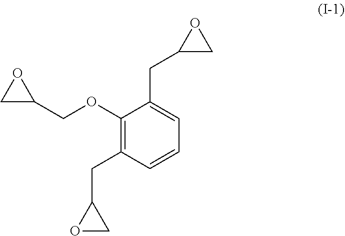 [SMILES: c1cc(CC2CO2)c(OCC2CO2)c(CC2CO2)c1]

in an amount of 3.91 wt %, the epoxy monomer represented by Formula (I-3)

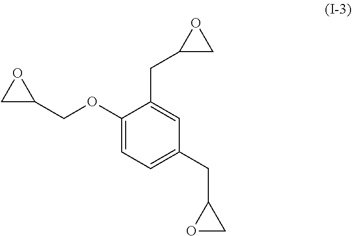 [SMILES: c1cc(OCC2CO2)c(CC2CO2)cc1CC1CO1]

in an amount of 2.19 wt %, and bisphenol F diglycidyl ether (serving as the second epoxy monomer) in an amount of 16.95 wt %, while the hardener mixture includes 4,4′-methylenebis(2-ethylaniline) in an amount of 7.77 wt % and 4,4′-methylenebis(2-methyl-6-ethylaniline) in an amount of 4.18 wt %. In EX7, based on 100 wt % of the curable composition, the first epoxy monomer mixture includes the epoxy monomer represented by Formula (I-1)

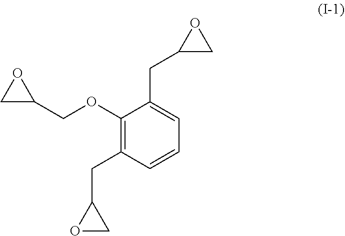 [SMILES: c1cc(CC2CO2)c(OCC2CO2)c(CC2CO2)c1]

in an amount of 3.90 wt %, the epoxy monomer represented by Formula (I-3)

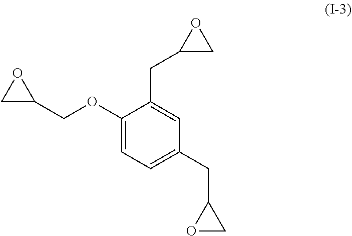 [SMILES: c1cc(OCC2CO2)c(CC2CO2)cc1CC1CO1]

in an amount of 2.18 wt %, and

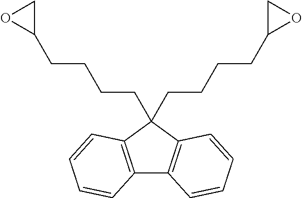 [SMILES: c1ccc2c(c1)-c1ccccc1C2(CCCCC1CO1)CCCCC1CO1]

(serving as the second epoxy monomer) in an amount of 17.5 wt %, while the hardener mixture includes 4,4′-methylenebis(2-ethylaniline) in an amount of 7.42 wt % and 4,4′-methylenebis(2-methyl-6-ethylaniline) in an amount of 4.00 wt %. In EX8, based on 100 wt % of the curable composition, the first epoxy monomer mixture includes the epoxy monomer represented by Formula (I-1)

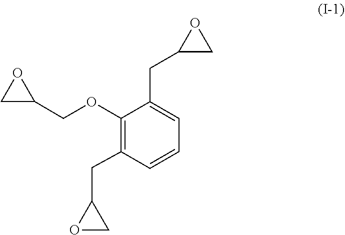 [SMILES: c1cc(CC2CO2)c(OCC2CO2)c(CC2CO2)c1]

in an amount of 3.78 wt %, the epoxy monomer represented by Formula (I-3)

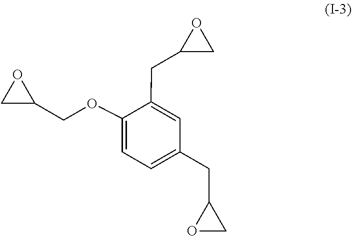 [SMILES: c1cc(OCC2CO2)c(CC2CO2)cc1CC1CO1]

in an amount of 2.12 wt %, and

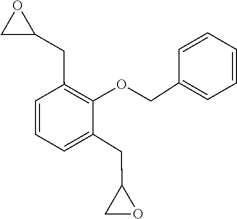 [SMILES: c1ccc(COc2c(CC3CO3)cccc2CC2CO2)cc1]

(serving as the second epoxy monomer) in an amount of 16.8 wt %, while the hardener mixture includes 4,4′-methylenebis(2-ethylaniline) in an amount of 8.00 wt % and 4,4′-methylenebis(2-methyl-6-ethylaniline) in an amount of 4.30 wt %.

### Example 9 (EX9)

First, based on 100 wt % of a curable composition, a first epoxy monomer mixture [including an epoxy monomer represented by Formula (I-1)

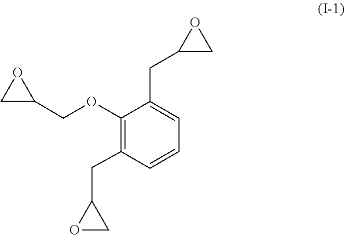 [SMILES: c1cc(CC2CO2)c(OCC2CO2)c(CC2CO2)c1]

in an amount of 3.78 wt % and an epoxy monomer represented by Formula (I-3)

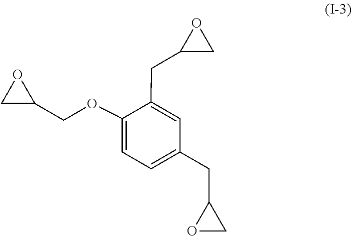 [SMILES: c1cc(OCC2CO2)c(CC2CO2)cc1CC1CO1]

in an amount of 2.12 wt %] in an amount of 5.90 wt %

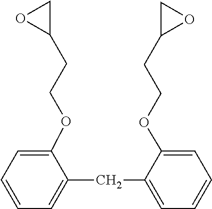 [SMILES: c1ccc(OCCC2CO2)c(Cc2ccccc2OCCC2CO2)c1]

in an amount of 0.58 wt % (serving as a second epoxy monomer),

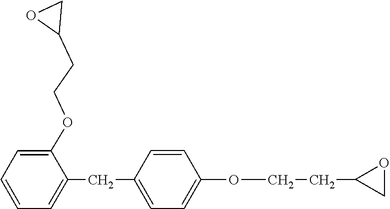 [SMILES: c1ccc(OCCC2CO2)c(Cc2ccc(OCCC3CO3)cc2)c1]

in an amount of 8.00 wt % (serving as a second epoxy monomer) and

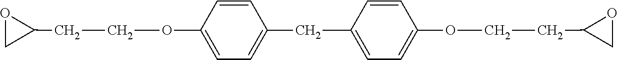 [SMILES: c1cc(OCCC2CO2)ccc1Cc1ccc(OCCC2CO2)cc1]

in an amount of 8.87 wt % (serving as a second epoxy monomer) were mixed, so as to form an epoxy monomer component (i.e., a second component), wherein the first epoxy monomer is present in a total amount of 25.3 wt % in the epoxy monomer component. Next, based on 100 wt % of the curable composition, a hardener mixture in an amount of 11.65 wt % [including 4,4′-methylenebis(2-ethylaniline) in an amount of 7.57 wt % and 4,4′-methylenebis(2-methyl-6-ethylaniline) in an amount of 4.08 wt %] and spherical silica in an amount of 65 wt % were mixed with the epoxy monomer component, thereby obtaining a curable composition of EX9.

### Comparative Example 1 (CE1)

First, based on 100 wt % of a curable composition, bisphenol F diglycidyl ether in an amount of 8.1 wt % and para-(2,3-epoxypropoxy)-N,N-bis(2,3-epoxypropyl)aniline in an amount of 22.5 wt % were mixed, so as to form an epoxy monomer component. Next, based on 100 wt % of the curable composition, a hardener mixture in an amount of 14.4 wt % [including 4,4′-methylenebis(2-ethylaniline) in an amount of 9.36 wt % and 4,4′-methylenebis(2-methyl-6-ethylaniline) in an amount of 5.04 wt %] and spherical silica in an amount of 55 wt % were mixed with the epoxy monomer component, thereby obtaining a curable composition of CE1.

### Comparative Examples 2 to 6 (CE2 to CE6)

The procedures and conditions for preparing the curable compositions of CE2 to CE6 were substantially similar to those of CE1, except that the types and/or amounts of the components were altered (see Table 3 below). In CE2, the hardener mixture includes 4,4′-methylenebis(2-ethylaniline) in an amount of 7.865 wt % and 4,4′-methylenebis(2-methyl-6-ethylaniline) in an amount of 4.235 wt % based on 100 wt % of the curable composition. In CE3, the hardener mixture includes 4,4′-methylenebis(2-ethylaniline) in an amount of 22.62 wt % and 4,4′-methylenebis(2-methyl-6-ethylaniline) in an amount of 12.18 wt % based on 100 wt % of the curable composition. In CE4, the hardener mixture includes 4,4′-methylenebis(2-ethylaniline) in an amount of 27.365 wt % and 4,4′-methylenebis(2-methyl-6-ethylaniline) in an amount of 14.735 wt % based on 100 wt % of the curable composition. In CE5, the hardener mixture includes 4,4′-methylenebis(2-ethylaniline) in an amount of 5.785 wt % and 4,4′-methylenebis(2-methyl-6-ethylaniline) in an amount of 3.115 wt % based on 100 wt % of the curable composition. In CE6, the hardener mixture includes 4,4′-methylenebis(2-ethylaniline) in an amount of 10.075 wt % and 4,4′-methylenebis(2-methyl-6-ethylaniline) in an amount of 5.425 wt % based on 100 wt % of the curable composition.

### Property Evaluation

Samples of the curable compositions of EX1 to EX9 and CE1 to CE6 were subjected to measurements described below. The results for the measurements are listed in Table 4 below.

### 1. Viscosity (Unit: Pa·s)

Each sample with a volume of 0.55 mL was placed in a rheometer (Manufacturer: TA Instruments; Model no.: AR2000ex), and then subjected to measurement of viscosity at 25° C. and 100° C., with a shear rate of 1 s⁻¹.

### 2. Water Absorption Rate (Unit: %)

First, each sample was subjected to a curing reaction conducted at 150° C. for 2 hours, so as to form a block-shaped cured product having a size of 0.8 cm×0.8 cm. Next, the block-shaped cured product was placed in an oven and then subjected to a drying treatment conducted at 150° C. for 1 hour, so as to obtain a dried cured product. Thereafter, the dried cured product was subjected to determination of weight. Afterwards, the dried cured product was subjected to the Highly Accelerated Stress Test (HAST) by placing into a pressure cooker testing machine (Manufacturer: King Son Ins. Tech Co., Ltd.; Model no.: Hast-A Plus), and then left to stand at a temperature of 120° C. and a relative humidity of 100% for 20 hours, followed by determination of weight. The water absorption rate was calculated using the following Equation A:

$$Water absorption rate = \{ [ ( {W}_{1} - {W}_{0} ) / {W}_{0} ] \div ( {W}_{2} + {W}_{3} ) \} \times 100 \% \qquad ( A )$$

in which
W₀=weight of the dried cured product before HAST
W₁=weight of the dried cured product after HAST
W₂=weight of the epoxy monomer component
W₃=weight of the hardener
   3. Adhesion Strength (Unit: kgf/mm²)

First, each sample was coated on a silicon carrier to form a cylindrical protrusion, followed by subjecting the cylindrical protrusion to a curing reaction conducted at 150° C. for 2 hours, so as to form a cylindrical cured product having a diameter of 0.4 mm and a height of 0.1 mm. Next, a portion of the cylindrical cured product was placed into the Bondtester (Manufacturer: Nordson; Model no.: DAGE 4000PXY), and then a lateral force was applied with increments thereof (i.e., from a relatively small lateral force to a relatively large lateral force) at 22° C. until the cylindrical cured product breaks, followed by determination of the lateral force causing the breakage, and calculation of the adhesion strength at room temperature using the following Equation (B):

$$Adhesion strength at room temperature = {X}_{1} \div {X}_{2} \qquad ( B )$$

in which
X₁=lateral force causing breakage at 22° C.
X₂=size of cross-sectional area of the cylindrical cured product

Subsequently, another portion of the cylindrical cured product was placed in an environment having a temperature of 110° C. for 2 minutes, then a lateral force was applied with increments thereof (i.e., from a relatively small lateral force to a relatively large lateral force) until the cylindrical cured product breaks, followed by determination of the lateral force causing the breakage, and calculation of the adhesion strength at high temperature using the following Equation (C):

$$Adhesion strength at room temperature = {Y}_{1} \div {Y}_{2} \qquad ( C )$$

in which
Y₁=lateral force causing breakage at 110° C.
Y₂=size of cross-sectional area of the cylindrical cured product

TABLE 1

| Curable composition | | | | EX1 | EX2 | EX3 | EX4 | EX5 |
|---|---|---|---|---|---|---|---|---|
| Epoxy monomer | First component | | | 0 | 0 | 0 | 56.9 | 29.5 |
| component (wt %) | Second | First epoxy monomer mixture | | 22.5 | 13.8 | 39.3 | 0 | 0 |
| | component | Second epoxy | Bisphenol F | 8.1 | 8.8 | 25 | 0 | 0 |
| | | monomer | diglycidyl ether | | | | | |
| | Total amount of first epoxy monomer in | | | 73.5 | 61.1 | 61.1 | 100 | 100 |
| | epoxy monomer component (wt %) | | | | | | | |
| Hardener mixture (wt %) | | | | 14.4 | 12.4 | 35.7 | 43.1 | 15.5 |
| Filler | Spherical silica | | | 55 | 65 | 0 | 0 | 55 |
| material (wt %) | | | | | | | | |

TABLE 2

| Curable composition | | | | EX6 | EX7 | EX8 | EX9 |
|---|---|---|---|---|---|---|---|
| Epoxy | Second | First epoxy monomer mixture | | 6.10 | 6.08 | 5.90 | 5.90 |
| monomer | component | Second epoxy | Bisphenol F diglycidyl ether | 16.95 | 0 | 0 | 0 |
| component | | monomer | | | | | |
| (wt %) | | | | | | | |
| | | | 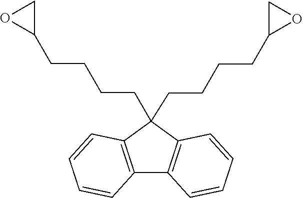 [SMILES: c1ccc2c(c1)-c1ccccc1C2(CCCCC1CO1)CCCCC1CO1] | 0 | 17.5 | 0 | 0 |
| | | | 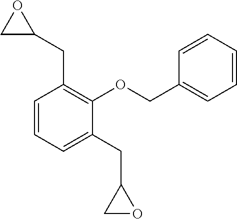 [SMILES: c1ccc(COc2c(CC3CO3)cccc2CC2CO2)cc1] | 0 | 0 | 16.8 | 0 |
| | | | 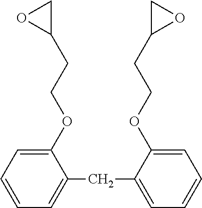 [SMILES: c1ccc(OCCC2CO2)c(Cc2ccccc2OCCC2CO2)c1] | 0 | 0 | 0 | 0.58 |
| | | | 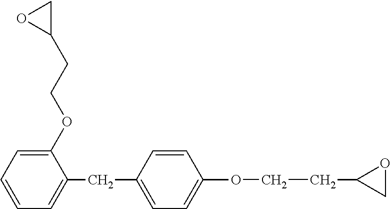 [SMILES: c1ccc(OCCC2CO2)c(Cc2ccc(OCCC3CO3)cc2)c1] | 0 | 0 | 0 | 8 |
| | | | 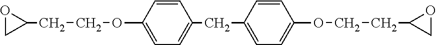 [SMILES: c1cc(OCCC2CO2)ccc1Cc1ccc(OCCC2CO2)cc1] | 0 | 0 | 0 | 8.87 |

| | Total amount of first epoxy monomer in epoxy monomer component (wt %) | 26.5 | 25.8 | 26.0 | 25.3 |
|---|---|---|---|---|---|
| Hardener mixture (wt %) | | 11.95 | 11.42 | 12.3 | 11.65 |
| Filler | Spherical silica | 65 | 65 | 65 | 65 |
| material | | | | | |
| (wt %) | | | | | |

TABLE 3

| Curable composition | | CE1 | CE2 | CE3 | CE4 | CE5 | CE6 |
|---|---|---|---|---|---|---|---|
| Epoxy monomer | Bisphenol F diglycidyl ether | 8.1 | 8.8 | 25 | 0 | 26.1 | 0 |
| component (wt %) | Para-(2,3-epoxypropoxy)-N,N-bis(2,3- | 22.5 | 14.1 | 40.2 | 57.9 | 0 | 29.5 |
| | epoxypropyl)aniline | | | | | | |
| Hardener mixture (wt %) | | 14.4 | 12.1 | 34.8 | 42.1 | 8.9 | 15.5 |
| Filler material (wt %) | Spherical silica | 55 | 65 | 0 | 0 | 65 | 55 |

TABLE 4

| | Property evaluation | | | | |
|---|---|---|---|---|---|
| | | | | Adhesion | Adhesion |
| | | | Water | strength at room | strength at high |
| | Viscosity (Pa · s) | | absorption | temperature | temperature |
| | 25° C. | 100° C. | rate (%) | (kgf/mm²) | (kgf/mm²) |
| EX1 | 3.4 | 0.09 | 3.82 | 2.8 ± 0.9 | — |
| EX2 | 6.4 | 0.20 | 2.46 | 2.2 ± 0.3 | 1.5 ± 0.3 |
| EX3 | 0.56 | — | 2.61 | 1.5 ± 0.4 | — |
| EX4 | 0.34 | — | 2.04 | — | — |
| EX5 | 2.5 | 0.08 | 3.80 | 1.4 ± 0.1 | — |
| EX6 | 8.6 | 0.42 | 2.17 | 5.2 ± 0.2 | — |
| EX7 | 10.2 | 0.31 | 2.20 | 2.6 ± 0.4 | — |
| EX8 | 3.5 | 0.41 | 2.74 | 5.2 ± 0.3 | — |
| EX9 | 4.8 | 0.45 | 2.66 | 5.1 ± 0.3 | — |
| CE1 | 4.1 | 0.10 | 4.00 | 2.6 ± 0.6 | — |
| CE2 | 10.1 | 0.33 | 2.57 | 2.1 ± 0.7 | — |
| CE3 | 0.68 | — | 2.73 | 1.4 ± 0.4 | — |
| CE4 | 0.66 | — | 2.43 | — | — |
| CE5 | 133 | 1.00 | 2.91 | 3.1 ± 0.4 | 0.6 ± 0.1 |
| CE6 | 2.8 | 0.10 | — | 1.1 ± 0.2 | — |

“—”: not determined

The results in Table 4 show that the viscosities at 25° C. of the curable compositions of EX1 to EX4 were respectively lower than those of the curable compositions of CE1 to CE4, and that the viscosity at 25° C. of the curable composition of EX5 was lower than that of the curable composition of CE6, indicating that the curable composition of the present disclosure, which includes the first epoxy monomer represented by Formula (I), indeed has a good flowability.

In addition, the water absorption rates of the cured products formed from the curable compositions of EX1 to EX4 were respectively lower than those of the cured products formed from the curable compositions of CE1 to CE4. To be specific, the water absorption rate of the cured product formed from the curable composition of EX1 was 4.5 wt % lower than that of the cured product formed from the curable composition of CE1 {[(4.00−3.82)÷4.00]×100 wt %}, the water absorption rate of the cured product formed from the curable composition of EX2 was 4.28 wt % lower than that of the cured product formed from the curable composition of CE2 {[(2.57−2.46)÷2.57]×100 wt %}, the water absorption rate of the cured product formed from the curable composition of EX3 was 4.40 wt % lower than that of the cured product formed from the curable composition of CE3 {[(2.73−2.61)÷2.73]×100 wt %}, and the water absorption rate of the cured product formed from the curable composition of EX4 was 16.05 wt % lower than that of the cured product formed from the curable composition of CE4 {[(2.43−2.04)÷2.43]×100 wt %}. These results indicate that, when the cured product formed from the curable composition of the present disclosure including the first epoxy monomer represented by Formula (I) serves as an underfill material to encapsulate an electronic device, during a reliability test at high temperature, the problem of the encapsulated electronic device easily cracks due to the presence of bubbles in the underfill material will not occur, resulting in the encapsulated electronic device having a good yield.

In addition, the results in Table 4 show that the viscosities at 25° C. of the curable compositions of EX6 to EX9 were lower than that of the curable composition of CE5, and that the water absorption rates of the cured products formed from the curable compositions of EX6 to EX9 were also lower than that of the cured product formed from the curable composition of CE5, indicating that the curable composition of the present disclosure, which includes the first epoxy monomer represented by Formula (I) in combination with the second epoxy monomer of different types, can meet the requirement of having an appropriate flowability, and the cured product formed from such curable composition can also meet the requirement of having a relatively low water absorption rate (i.e., a relatively low hygroscopicity).

In summary, by inclusion of the first epoxy monomer represented by Formula (I), the curable composition of the present disclosure has a low viscosity and an appropriate flowability, and since the cured product formed from the curable composition has a relatively low water absorption rate (i.e., a relatively low hygroscopicity), when the cured product serves as an underfill material to encapsulate an electronic device, during the reliability test at high temperature, the problem of the encapsulated electronic device easily cracks due to presence of bubbles in the underfill material will not occur, resulting in the encapsulated electronic device having a good yield. Therefore, the purpose of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A curable composition, comprising:
an epoxy monomer component selected from one of a first component and a second component, the first component being formed from at least one of a first epoxy monomer represented by Formula (I), the second component including the at least one of the first epoxy monomer represented by Formula (I) and at least one of a second epoxy monomer that is different from the first epoxy monomer represented by Formula (I),
wherein based on 100 wt % of the epoxy monomer component, the first epoxy monomer represented by Formula (I) is present in an amount of not smaller than 25 wt % and less than 100 wt % and the second epoxy monomer is present in an amount of greater than 0 wt % and not greater than 75 wt %,
wherein 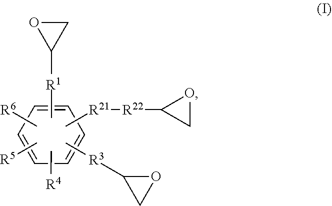
each of R¹, R²² and R³ is independently a C₁-C₃ alkylene group,
R²¹ is one of a single bond and oxygen, and
each of R⁴, R⁵ and R⁶ is independently one of hydrogen and a C₁-C₃ alkyl group; and
at least one of an aniline-based hardener.

2. The curable composition as claimed in claim 1, wherein the first epoxy monomer represented by Formula (I) is selected from the group consisting of an epoxy monomer represented by Formula (I-1) 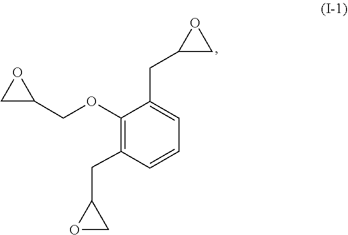 [SMILES: c1cc(CC2CO2)c(OCC2CO2)c(CC2CO2)c1]
an epoxy monomer represented by Formula (I-2) 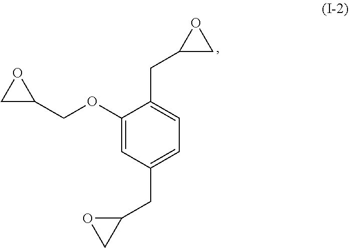 [SMILES: c1cc(CC2CO2)c(OCC2CO2)cc1CC1CO1]
an epoxy monomer represented by Formula (I-3) 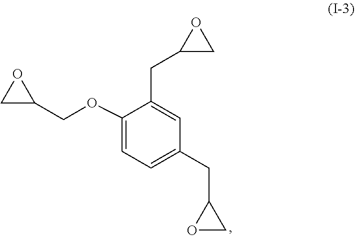 [SMILES: c1cc(OCC2CO2)c(CC2CO2)cc1CC1CO1]
an epoxy monomer represented by Formula (I-4) 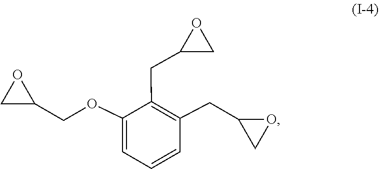 [SMILES: c1cc(CC2CO2)c(CC2CO2)c(OCC2CO2)c1]
and an epoxy monomer represented by Formula (I-5)

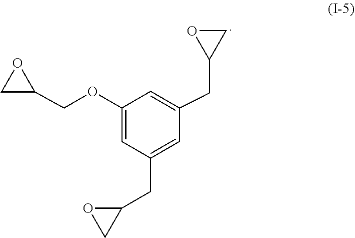 [SMILES: c1c(CC2CO2)cc(OCC2CO2)cc1CC1CO1]

3. The curable composition as claimed in claim 1, wherein the epoxy monomer component is the first component.

4. The curable composition as claimed in claim 1, wherein the epoxy monomer component is the second component.

5. The curable composition as claimed in claim 4, wherein the first epoxy monomer represented by Formula (I) is present in an amount of not smaller than 60 wt % and less than 100 wt % based on 100 wt % of the epoxy monomer component.

6. The curable composition as claimed in claim 1, wherein the epoxy monomer component is present in an amount ranging from 5 wt % to 65 wt % based on 100 wt % of the curable composition.

7. The curable composition as claimed in claim 1, wherein the second epoxy monomer is an epoxy monomer having two epoxy groups and a plurality of aromatic rings.

8. The curable composition as claimed in claim 7, wherein the epoxy monomer having the two epoxy groups and the plurality of aromatic rings is selected from the group consisting of 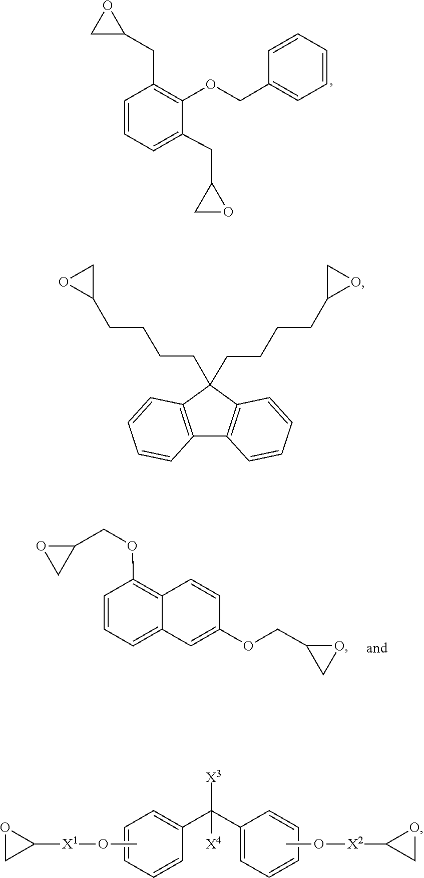
wherein
each of X¹ and X² is independently a C₁-C₃ alkylene group, and
each of X³ and X⁴ is independently one of hydrogen and a methyl group.

9. The curable composition as claimed in claim 1, further comprising at least one of a filler material.

10. The curable composition as claimed in claim 9, wherein the filler material is present in an amount of greater than 0 wt % and not greater than 70 wt % based on 100 wt % of the curable composition.

11. The curable composition as claimed in claim 9, wherein the filler material is selected from the group consisting of alumina and spherical silica.

12. A cured product, which is formed by subjecting a curable composition as claimed in claim 1 to a curing reaction.

13. The cured product as claimed in claim 12, which serves as an underfill material that is disposed in a gap between a carrier and a semiconductor element of a semiconductor device to encapsulate the semiconductor device.

14. A method for encapsulating a semiconductor device, comprising introducing a curable composition as claimed in claim 1 into a gap between a carrier and a semiconductor element of the semiconductor device, followed by conducting a curing reaction.
